(19) United States
(12) Patent Application Publication
(10) Pub. No.: US 2008/0272423 A1
(43) Pub. Date: Nov. 6, 2008

(54) Conductive structures, non-volatile memory device including conductive structures and methods of manufacturing the same

(76) Inventors: Byung-Yong Choi, Seoul (KR); Kyu-Charn Park, Gyeonggi-do (KR); Choong-Ho Lee, Gyeonggi-do (KR)

Correspondence Address: MYERS BIGEL SIBLEY & SAJOVEC, PO BOX 37428, RALEIGH, NC, 27627, US

(21) Appl. No.: 12/151,033

(22) Filed: May 2, 2008

(30) Foreign Application Priority Data
May 3, 2007 (KR) 2007-0043216

(51) Int. Cl. H01L 29/00; H01L 21/44

(52) U.S. Cl. 257/314; 438/675; 257/E29.001; 257/E21.476

(57) ABSTRACT

Conductive structures in an integrated circuit device including an integrated circuit substrate and first conductive layer patterns on the substrate. Second conductive layer patterns are on the substrate extending between respective ones of the first conductive layer patterns. Adjacent ones of the first and second conductive layer patterns are on different horizontal planes relative to the substrate to reduce parasitic capacitance therebetween.

### CROSS-REFERENCE TO RELATED APPLICATION

This application is related to and claims priority under 35 U.S.C. § 119 from Korean Patent Application No. 2007-43216, filed on May 3, 2007 in the Korean Intellectual Property Office (KIPO), the contents of which are herein incorporated by reference in their entirety.

### BACKGROUND OF THE INVENTION

The present invention relates to conductive structures in semiconductor devices and methods of forming the same, and more particularly, to a conductive structure including a conductive layer pattern and a contact plug and methods of forming the same.

Semiconductor (integrated circuit) memory devices generally require ever higher degrees of integration while retaining high performance. Thus, widths of conductive layer patterns, such as bit lines, word lines, etc., in the semiconductor memory devices, and intervals between the conductive layer patterns are generally decreasing.

The bit lines in the semiconductor memory devices may have low resistance and narrow pitches. Here, a pitch may correspond to a width from one end of a bit line to one end of an adjacent bit line. To reduce the resistance of the bit lines, the heights of the bit lines may be increased. Further, to reduce the pitches between the bit lines, intervals between the bit lines may be decreased.

However, when the bit lines have high heights and narrow intervals, loading capacitances between the adjacent bit lines may be greatly increased. This may deteriorate operational characteristics of the semiconductor memory device. Problems that may be generated by interference between the bit lines in a NAND flash memory device will now be further described.

In a NAND flash memory device, word lines may be arranged in parallel with each other along an x-direction. Each of the word lines may form a single unit cell. Sixteen or thirty-two word lines may be included in a single string. A cell selection line and a ground selection line may be provided to both ends of the string. A common source line may be electrically connected to impurity regions in a semiconductor substrate adjacent to the ground selection line. Further, a bit line structure may be electrically coupled to the impurity regions in the semiconductor substrate adjacent to the cell selection line. The bit line structure may include a bit line substantially perpendicular to the word line, and a contact plug connected between the bit line and the semiconductor substrate.

Although a selected bit line is generally electrically isolated from an adjacent bit line, an intercapacitance may be parasitically generated between the adjacent bit lines, particularly when an interval between the adjacent bit lines is very narrow. The intercapacitance may increase the capacitance between the adjacent bit lines so that a sensing time may be lengthened. The sensing time may correspond to a voltage change duration of the bit line for sensing a voltage change of the bit line in reading data, storing the sensed voltage change in a circuit of a buffer, and changing data in a latch circuit. When the sensing time is too long, the flash memory device may have an unacceptably slow operational speed.

To program data in a selected cell may require application of a high voltage to a bit line corresponding to the selected cell. However, as a result, the adjacent bit line may have a slightly increased voltage, and may not be maintained in a floating state, due to the influence of the voltage applied to the selected bit line. As a result, undesired data may be programmed in a floating gate electrode of the non-selected cell.

### SUMMARY OF EMBODIMENTS OF THE INVENTION

Embodiments of the present invention provide a conductive structure in an integrated circuit device including an integrated circuit substrate and first conductive layer patterns on the substrate. Second conductive layer patterns are on the substrate extending between respective ones of the first conductive layer patterns. Adjacent ones of the first and second conductive layer patterns are on different horizontal planes relative to the substrate to reduce parasitic capacitance therebetween.

In other embodiments, a first insulation interlayer is on the substrate, wherein the first conductive layer patterns are on the first insulation interlayer and an insulation member covers the first conductive layer patterns. The insulation member defines recesses between the first conductive layer patterns. The second conductive layer patterns are in the recesses. The second conductive layer patterns have a lower face higher than a lower face of the first conductive layer patterns to provide the different horizontal planes. The insulation member may be silicon oxynitride, silicon nitride and/or silicon oxide.

In further embodiments a spacer contacts sidewalls of the first conductive layer patterns, the spacer having an upper face higher than an upper face of the first conductive layer patterns. The first conductive layer patterns and the second conductive layer pattern may have an upper width and a lower width with the lower width being narrower than the upper width.

In other embodiments, an underlying structure in a unit cell of a memory device is on the substrate under the conductive layer patterns. The underlying structure may include a tunnel oxide layer, a charge storage pattern, a dielectric layer and a control gate. An etch-stop layer pattern may be on the first insulation interlayer. The insulation member may include a first insulation layer pattern on upper faces of the first conductive layer patterns and a second insulation layer on the first insulation layer pattern and extending between adjacent ones of the first conductive layer patterns to define the recesses therebetween.

In further embodiments, a non-volatile memory device includes a conductive structure as described previously. The non-volatile memory device includes a first region and a second region in the substrate. The first insulation interlayer and the insulation member are on the first region and the second region of the substrate and the first and second conductive layer patterns are in the first region of the substrate. Unit cells are on the first region of the substrate. The unit cells include an associated gate structure including a tunnel oxide layer, a charge storage pattern, a dielectric layer and a control gate. A second insulation interlayer is on the second conductive layer patterns in the first region and the insulation member in the second region. A first contact plug extends through the second insulation interlayer, the insulation member, the first conductive layer patterns and the first insulation interlayer to contact the substrate. The first contact plug is electrically connected to the first conductive layer patterns. A second contact plug extends through the second insulation interlayer, the insulation member, the second conductive layer patterns and the first insulation interlayer to contact the substrate. The second contact plug is electrically connected to the second conductive layer patterns. First dummy patterns and second dummy patterns may be on the first insulation interlayer in the second region.

In other embodiments, the insulation member includes a first insulation layer pattern on upper faces of the first conductive layer patterns and a second insulation layer on the first insulation layer pattern and extending between adjacent ones of the first conductive layer patterns to define the recesses therebetween. The first insulation layer pattern is not in the second region and the second insulation layer extends into the second region.

In yet further embodiments, methods of forming a conductive structure include forming a first insulation interlayer on a substrate and forming first conductive layer patterns on the first insulation interlayer. An insulation member is formed that covers the first conductive layer patterns and defines recesses between adjacent ones of the first conductive layer patterns. Second conductive layer patterns are formed in the recesses of the insulation member. The second conductive layer patterns have a lower face higher than a lower face of the first conductive layer patterns so that adjacent ones of the first and second conductive layer patterns are on different horizontal planes relative to the substrate to reduce parasitic capacitance therebetween.

In other embodiments, forming the first conductive layer patterns includes forming sacrificial layer patterns on the first insulation interlayer. A space between the sacrificial layer patterns is filled with a first conductive layer. The first conductive layer is partially removed to form the first conductive layer patterns in the space between the sacrificial layer patterns. A spacer may be formed on a sidewall of each of the sacrificial layer patterns. Partially removing the first conductive layer may be followed by removing the sacrificial layer patterns.

In further embodiments, forming the insulation member includes forming a first insulation layer on the first conductive layer patterns and the first insulation interlayer. The first insulation layer is partially etched until a portion of the first insulation layer on the first insulation interlayer is removed to form a first insulation layer pattern. A second insulation layer is formed on the first insulation interlayer and the first insulation layer pattern. The first insulation layer pattern may have a spacer shape on a sidewall of each of the first conductive layer patterns.

In other embodiments, forming the second conductive layer pattern includes forming a second conductive layer on the insulation member that fills the recesses of the insulation member and partially removing the second conductive layer to form the second conductive layer pattern in the recesses. An etch-stop layer may be formed on the first insulation interlayer.

In yet further embodiments, methods of manufacturing a non-volatile memory device structure include providing a substrate having a first region and a second region and forming unit cells on the first region of the substrate, each of the unit cells including a tunnel oxide layer, a charge storage pattern, a dielectric layer and a control gate. A first insulation interlayer is formed on the first region and the second region of the substrate. First conductive layer patterns are formed on the first insulation interlayer in the first region. An insulation member is formed covering the first conductive layer patterns in the first region. The insulation member defines recesses between adjacent ones of the first conductive layer patterns. Second conductive layer patterns are formed in the recesses of the insulation member. The second conductive layer patterns have a lower face higher than that of the first conductive layer patterns. A second insulation interlayer is formed on the second conductive layer patterns in the first region and on the insulation member in the second region. The second insulation interlayer, the insulation member, the first insulation interlayer, the first conductive layer patterns and the second conductive layer patterns are partially etched until an upper face of the substrate is exposed to form openings. The openings are filled with a conductive material to form a first contact plug electrically connected to the first conductive layer patterns and contacting the substrate and a second contact plug electrically connected to the second conductive layer patterns and contacting the substrate.

In other embodiments, forming the first conductive layer patterns includes forming a sacrificial layer on the first insulation interlayer in the first region and the second region. The sacrificial layer in the first region is partially etched to form a sacrificial layer pattern. A first conductive layer is formed in a space between the sacrificial layer patterns in the first region and the sacrificial layer on the second region. The first conductive layer in the second region is partially removed to form the first conductive layer patterns in the space between the sacrificial layer patterns.

In further embodiments, forming the insulation member includes forming a first insulation layer on the first conductive layer patterns and the first insulation interlayer that fills a space between the first conductive layer patterns in the second region. The first insulation layer is partially etched until a portion of the first insulation layer on the first insulation interlayer is removed to form a first insulation layer pattern. A second insulation layer is formed on the first insulation interlayer and the first insulation layer pattern. An etch-stop layer may be formed on the first insulation interlayer. Forming the first conductive layer patterns may be preceded by forming spacers on both sides of the first dummy pattern in the second region and the first conductive layer patterns.

In other embodiments, forming the first dummy patterns and the spacers includes forming sacrificial layer patterns on the first insulation interlayer in the first region and the second region. A first insulation layer is formed on the sacrificial layer patterns that fill spaces between the sacrificial layer patterns in the second region. The first insulation layer is anisotropically etched to form the first dummy patterns between the sacrificial layer patterns in the second region and the spacers on the sidewall of the sacrificial layer patterns in the first region. Forming the first conductive layer patterns may include forming a first conductive layer that fills the space between the spacers in the first region and partially removing the first conductive layer to form the first conductive layer patterns in the space between the spacers.

### BRIEF DESCRIPTION OF THE DRAWINGS

The present invention will become more fully understood from the detailed description given hereinbelow and the accompanying drawings which are given by way of illustration only, and thus are not limitative of the present invention, and wherein:

FIG. 1 is a cross-sectional view illustrating a conductive structure in accordance with some embodiments of the present invention;

FIGS. 2 to 8 are cross-sectional views illustrating a method of forming the conductive structure of FIG. 1;

FIG. 9 is a cross-sectional view illustrating a flash memory device in accordance with some embodiments of the present invention;

FIG. 10 is a perspective view illustrating a cell region of the flash memory device of FIG. 9;

FIGS. 11 to 21 are cross-sectional views illustrating a method of manufacturing the flash memory device of FIGS. 9 and 10 according to some embodiments;

FIG. 22 is a cross-sectional view illustrating a peripheral circuit region of a flash memory device in accordance with further embodiments of the present invention; and

FIGS. 23 to 27 are cross-sectional views illustrating a method of manufacturing the flash memory device of FIG. 22 according to some embodiments of the present invention.

### DETAILED DESCRIPTION OF THE EMBODIMENTS

The present invention is described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. In the drawings, the sizes and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like reference numerals refer to like elements throughout. As used herein, the term “and/or” includes any and all combinations of one or more of the associated listed items.

It will be understood that, although the terms first, second, etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of the invention. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Embodiments of the present invention are described herein with reference to cross-section illustrations that are schematic illustrations of idealized embodiments (and intermediate structures) of the present invention. As such, variations from the shapes of the illustrations as a result, for example, of manufacturing techniques and/or tolerances, are to be expected. Thus, embodiments of the present invention should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the present invention.

Unless otherwise defined, all terms (including technical and scientific terms) used herein have the same meaning as commonly understood by one of ordinary skill in the art to which the present invention belongs. It will be further understood that terms, such as those defined in commonly used dictionaries, should be interpreted as having a meaning that is consistent with their meaning in the context of the relevant art and this specification and will not be interpreted in an idealized or overly formal sense unless expressly so defined herein.

Some embodiments of the present invention will now be described with reference to FIG. 1. FIG. 1 is a cross-sectional view illustrating a conductive structure in a semiconductor device according to some embodiments of the present invention. As illustrated in FIG. 1, the conductive structure includes a first insulation interlayer 102, first conductive layer patterns 110, an insulation member 115, and second conductive layer patterns 118.

The first insulation interlayer 102 is formed on an integrated circuit substrate 100. The substrate 100 may include a semiconductor material, such as single crystalline silicon.

An underlying structure for forming a unit cell of a flash memory device may be formed on the substrate 100. For example, the underlying structure may include a sequentially stacked tunnel oxide layer, charge storage layer, dielectric layer and control gate electrode. The underlying structure may form the unit cell of the flash memory device.

The first insulation interlayer 102 may include silicon oxide. When the underlying structure is formed on the substrate 100, the first insulation interlayer 102 may have a sufficient thickness to cover the underlying structure. Further, the first insulation interlayer 102 may have a flat upper face.

Etch-stop layer patterns 104a are formed on the first insulation interlayer 102. The etch-stop layer patterns 104a may include silicon nitride.

The first conductive layer patterns 110 are formed on the first insulation interlayer 102 between the etch-stop layer patterns 104a. The first conductive layer patterns 110 may include a metal, a doped semiconductor material and/or the like. Examples of a material that may be used for the first conductive layer patterns 110 may include tungsten, tungsten nitride, copper, polysilicon and/or the like.

The first conductive layer patterns 110 may have an upper width, and a lower width narrower than the upper width. Each of the first conductive layer patterns 110 may have a shape having a width that gradually widens from a lower end to the upper end of the first conductive layer patterns 110.

Each of spacers 108 is formed on a sidewall of each of the first conductive layer patterns 110. Each of the spacers 108 may have an upper face higher than that of each of the first conductive layer patterns 110. Thus, the spacers 108 may be protruded from the first conductive layer patterns 110.

The insulation member 115 covers the first conductive layer patterns 110. The insulation member 115 has recesses located between the first conductive layer patterns 110.

The insulation member 115 includes a first insulation layer pattern 112 and a second insulation layer 114. The first insulation layer pattern 112 makes contact with upper faces of the first conductive layer patterns 110 and both side faces of the spacers 108. The second insulation layer 114 is formed on the first insulation layer pattern 112, the spacers 108 and the etch-stop layer patterns 104a.

The first insulation layer pattern 112 may include a material having an etching selectivity different from that of the spacers 108. For example, the first insulation layer pattern 112 may include silicon oxynitride, silicon oxide and/or the like. The second insulation layer 114 may include silicon oxynitride, silicon oxide and/or the like. The first insulation layer pattern 112 and the second insulation layer 114 may be the same material or different materials.

The second conductive layer patterns 118 are formed in the recesses of the insulation member 115. Each of the illustrated second conductive layer patterns 118 may have a lower face higher than that of each of the first conductive layer patterns 110.

The second conductive layer patterns 118 may be the same material as that of the first conductive layer patterns 110. Each of the second conductive layer patterns 118 may have an upper width, and a lower width narrower than the upper width. Each of the second conductive layer patterns 118 may have a shape having a width that gradually widens from a lower end to the upper end of the second conductive layer patterns 118.

For the illustrated conductive structure, the first conductive layer patterns and the second conductive layer patterns may not be coplanar with each other. Thus, the first conductive layer patterns and the second conductive layer patterns may have comparatively small areas facing each other (i.e., a lower and upper faces of patterns 118 are higher than corresponding lower and upper faces of patterns 110 as seen in the embodiments of FIG. 1) so that parasitic capacitance between the first conductive layer pattern 110 and the second conductive layer pattern 118 may be reduced. As a result, a signal transmission speed through the first conductive layer pattern and the second conductive layer patterns may become faster.

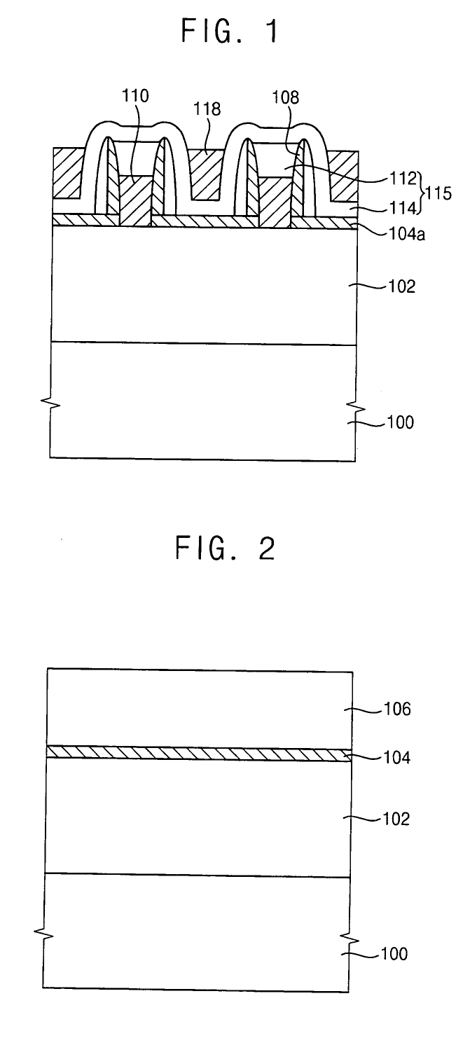

FIGS. 2 to 8 are cross-sectional views illustrating a method of forming the conductive structure in FIG. 1 according to some embodiments of the present invention. Referring first to FIG. 2, the substrate 100, including a semiconductor material, such as single crystalline silicon, is prepared. An underlying structure for forming the unit cell of the flash memory device may be formed on the substrate 100. For example, the underlying structure may include a tunnel oxide layer, a charge storage layer, a dielectric layer and a control gate electrode, which may be sequentially stacked.

The first insulation interlayer 102 is formed on the substrate 100. The first insulation interlayer 102 may be formed by a chemical vapor deposition (CVD) process using silicon oxide. An etch-stop layer 104 is formed on the first insulation interlayer 102. The etch-stop layer 104 may be formed by a CVD process using silicon nitride. A sacrificial layer 106 is formed on the etch-stop layer 104. The sacrificial layer 106 may include a material having etching selectivity with respect to the etch-stop layer 104. For example, the sacrificial layer 106 may include silicon oxide, polysilicon, etc.

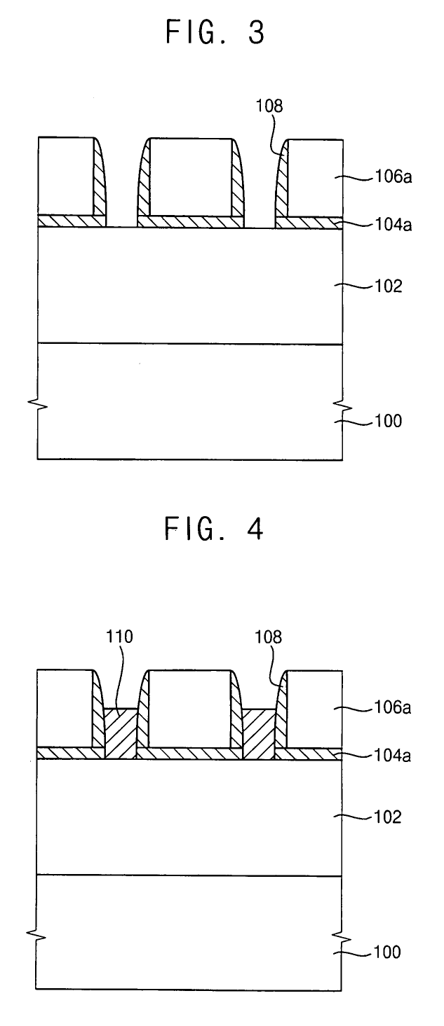

Referring to FIG. 3, the sacrificial layer 106 is patterned, for example, by a photolithography process, to form sacrificial layer patterns 106a. The first conductive layer patterns 110 are formed in a region between the sacrificial layer patterns 106a as seen in FIG. 4. The second conductive layer patterns 118 are formed in a region defined by the formed sacrificial layer patterns 106a as seen in FIG. 8.

A silicon nitride layer is formed on the sacrificial layer pattern 106a and the etch-stop layer 104. The silicon nitride layer may be anisotropically etched to form spacers 108 on sidewalls of the sacrificial layer patterns 106a. The etch-stop layer 106 between the sacrificial layer patterns 104a may be partially removed by the anisotropic etching process to form the etch-stop layer patterns 104a.

A first conductive layer is formed on the etch-stop layer patterns 104a that fills spaces between the spacers 108. The first conductive layer may include a metal, a semiconductor material doped with impurities, etc. Examples of a material that may be used for the first conductive layer may include tungsten, tungsten silicide, copper, polysilicon, etc.

As seen in FIG. 4, the first conductive layer is partially removed to form the first conductive layer patterns 110 between the spacers 108. The first conductive layer patterns 110 may have an upper face lower than upper faces of the spacers 108.

The first conductive layer may be removed by performing a chemical mechanical polishing (CMP) process on the first conductive layer until the sacrificial layer pattern 106a is exposed, and etching back the polished first conductive layer. In this case, the height of the first conductive layer patterns 110 may be controlled by controlling an etched thickness of the first conductive layer during the etch-back process. As a result, the resistance of the first conductive layer patterns 110 may be controlled. However, the first conductive layer may be etched back to form the first conductive layer patterns 110 without performing a CMP process on the first conductive layer.

The spacers 108 may have a shape having an upper width, and a lower width greater than the upper width. Further, each of the spacers 108 may have a rounded sidewall. Thus, each of the first conductive layer patterns 110 between the spacers 108 may have an upper width, and a lower width less than the upper width.

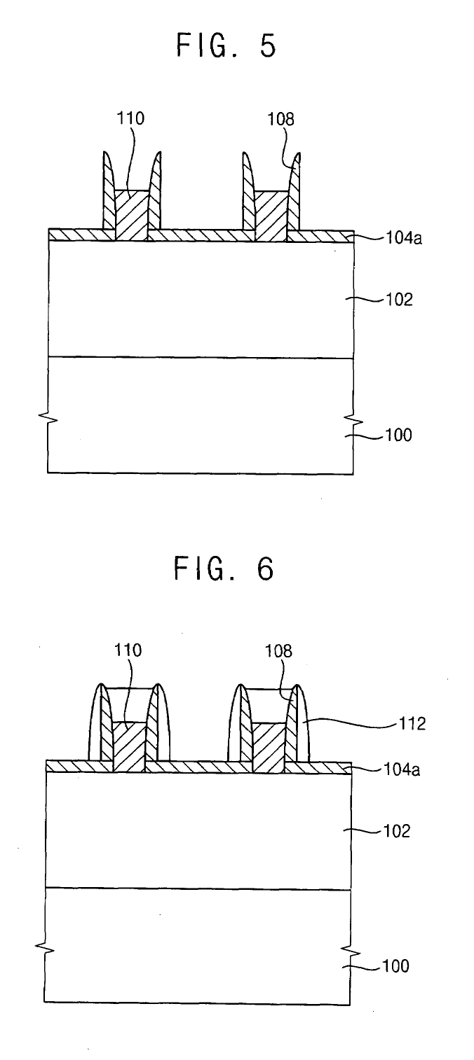

Referring to FIG. 5, the sacrificial layer pattern 106a is removed. To reduce the risk of the spacers 108 and the first conductive layer patterns 110 being damaged during the removal of the sacrificial layer pattern 106a, the sacrificial layer pattern 106a may be removed by a wet etching process.

A first insulation layer is formed on the first conductive layer patterns 110, the spacers 18 and the etch-stop layer patterns 104a. The first insulation layer may be the same or a different material than the spacers 108. For example, the first insulation layer may include silicon oxynitride, silicon oxide, silicon nitride, etc. In some embodiments, the silicon oxynitride is deposited by a CVD process to form the first insulation layer.

As seen in FIG. 6, the first insulation layer is anisotropically etched to form the first insulation layer pattern 112 on the sidewalls of the spacers 108 and the first conductive layer patterns 110. The first insulation layer pattern 112 on the sidewalls of the spacers 108 may have a general spacer shape. The etch-stop layer patterns 104a may be etched during the process of anisotropically etching the first insulation layer.

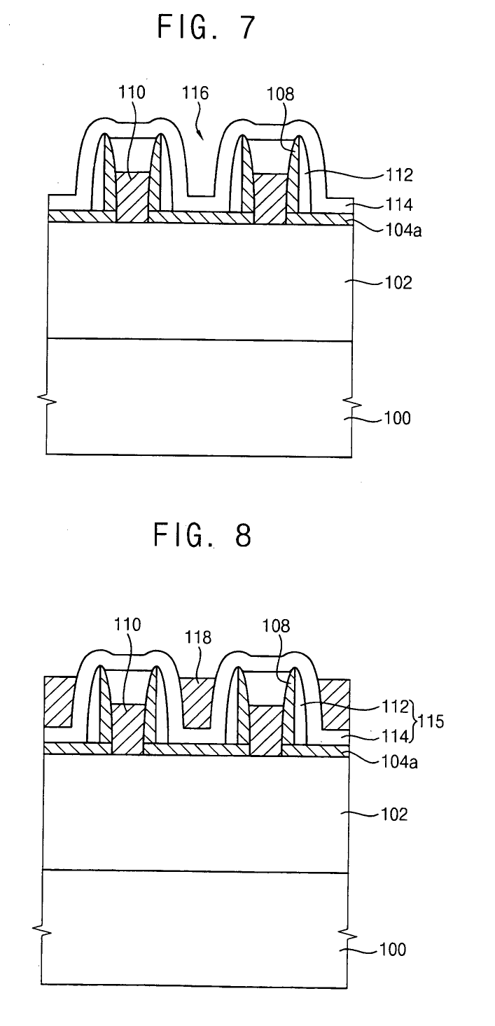

Referring to FIG. 7, the second insulation layer 114 is formed on the first insulation layer pattern 112, the spacers 108 and the etch-stop layer patterns 104a. The second insulation layer 114 may be the same material or a different material than the first insulation layer pattern 112. The recesses 116 are defined between the first insulation layer patterns 112 by forming the second insulation layer 114. The recesses 116 may have a bottom face higher than a lower face of each of the first conductive layer patterns 110.

A second conductive layer is formed on the second insulation layer 114 to fill up the recesses 116. The second conductive layer may include the same material as that of the first conductive layer pattern 110.

As seen in FIG. 8, the second conductive layer is partially removed to form the second conductive layer patterns 118 in the recesses 116. The removal of the second conductive layer may be performed by an etch-back process, a CMP process, etc.

Using the method described with reference to FIG. 2-8, the conductive structure including the first conductive layer patterns and the second conductive layer patterns may be formed. The first conductive layer patterns and the second conductive layer patterns may not be placed on the same horizontal plane. The method of forming the conductive structure may include a single photolithography process so that the method may be very simple. Further, the first conductive layer patterns and the second conductive layer patterns may be formed by a damascene process. Thus, the first conductive layer patterns and the second conductive layer patterns may be formed using various conductive materials.

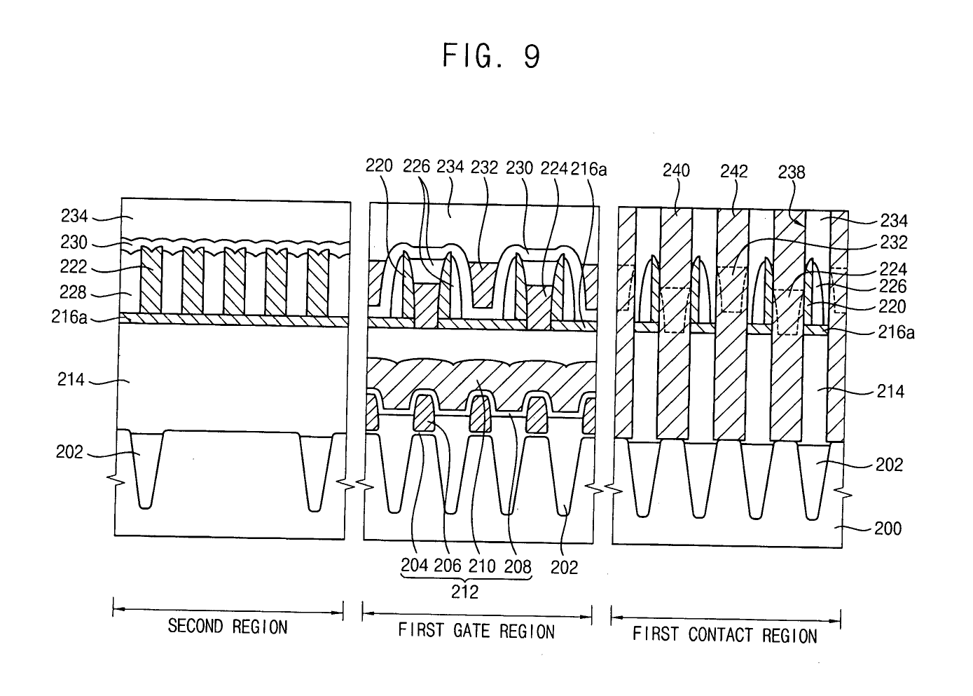

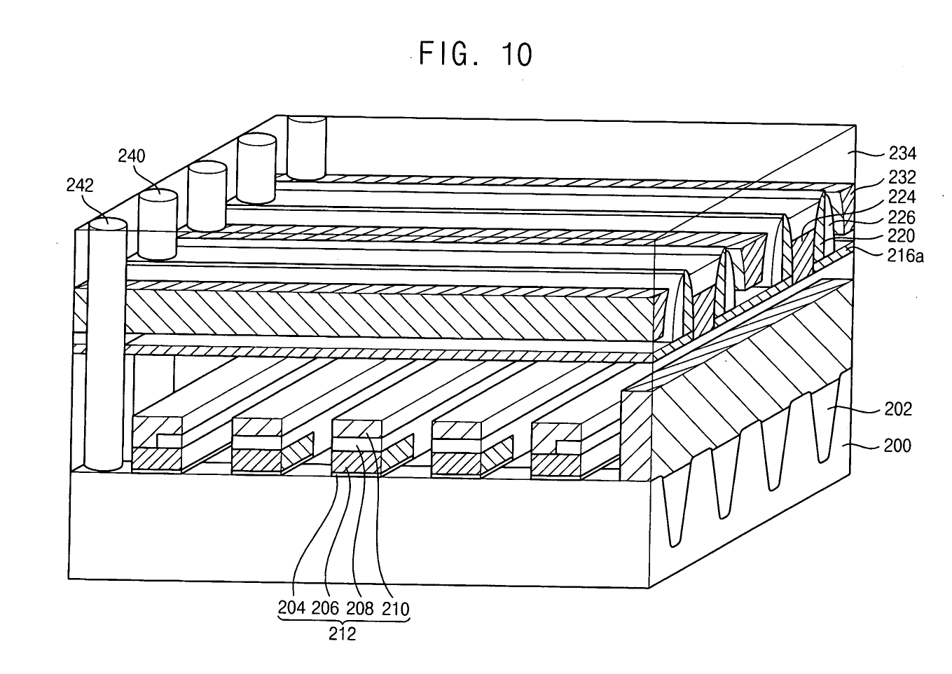

Further embodiments of the present invention will now be described with reference to FIGS. 9 and 10. FIG. 9 is a cross-sectional view illustrating a flash memory device in accordance with some embodiments of the present invention, and FIG. 10 is a perspective view illustrating a cell region of the flash memory device of FIG. 9.

In FIG. 9, a first region corresponds to a cell region. The first region has a first gate region corresponding to a region where a cell transistor is formed, and a first contact region corresponding to a region where a bit line contact is formed. A second region corresponds to a peripheral circuit region.

Referring to FIGS. 9 and 10, a substrate 200 having the first region and the second region is prepared. Unit cells are formed in the first region. Peripheral circuits are formed in the second region. The substrate 200 may include a semiconductor material, such as single crystalline silicon.

Trenches are formed in isolation regions of the substrate 200. The trenches in the first region may be arranged in parallel with each other. The trenches extend along a first direction. Inner wall oxide layers are formed on inner faces of the trenches. The inner wall oxide layers may be formed by a thermal oxidation process using silicon oxide.

Isolation layer patterns 202 are formed in the trenches. Each of the isolation layer patterns 202 has an upper face protruded from an upper face of the substrate 200. The isolation layer patterns 202 divide the substrate 200 into active regions and the isolation regions. The active regions and the isolation regions have a linear shape extending along the first direction. Further, the active regions and the isolation regions are alternately arranged. The isolation layer patterns 202 may be formed by a CVD process using silicon oxide.

Cell gate structures 212 are formed in the first region. Each of the cell gate structures 212 includes a tunnel oxide layer 204, a charge storage layer pattern 206, a dielectric layer pattern 208 and a control gate electrode 210 sequentially stacked. Impurity regions are formed at both sides of the cell gate structures 212. The cell gate structures 212 and the impurity regions are provided as a cell transistor.

The charge storage layer pattern 206 may include polysilicon doped with impurities. The charge storage layer pattern 206 may be used as a floating gate electrode. The charge storage layer pattern 206 may include silicon nitride and the charge storage layer pattern 206 may be used as a charge-trapping pattern.

The cell transistors, for example, sixteen or thirty-two cell transistors, are connected to each other in series to form a single string. A cell selection transistor and a ground selection transistor are connected to ends of the cell transistor in the single string. The cell selection transistor and the ground selection transistor may include a gate pattern including a gate oxide layer and a gate electrode sequentially stacked, and impurity regions at both sides of the gate pattern.

A first insulation interlayer 214 is formed on the first region where the cell transistor, the cell selection transistor and the ground selection transistor are formed, and the second region. The first insulation interlayer 214 fully covers the cell transistor, the cell selection transistor and the ground selection transistor. Further, the first insulation interlayer 214 may have a flat upper face.

Etch-stop layer patterns 216a are formed on the first insulation interlayer 214. The etch-stop layer patterns 216a may include silicon nitride.

The first conductive layer patterns 224 are formed on the first insulation interlayer 214 in the first region. The first conductive layer patterns 224 may be used as a bit line. The etch-stop layer patterns 216a may not be formed under the first conductive layer patterns 224. The first conductive layer patterns 224 may include a metal, a doped semiconductor material, etc. Examples of a material that may be used for the first conductive layer patterns 224 may include tungsten, tungsten nitride, copper, polysilicon, etc.

Each of spacers 220 is formed on a sidewall of each of the first conductive layer patterns 224. The spacers 220 may have an upper face higher than that of the first conductive layer patterns 224. Thus, the spacers 220 may be protruded from the first conductive layer patterns 224.

First dummy patterns 222 may be formed on the first insulation interlayer 224 in the second region. The first dummy patterns 222 may be the same material as that of the spacers 220. Further, each of the first dummy patterns 222 may have a very narrow width. Furthermore, the first dummy patterns 222 may be arranged spaced apart from each other by a very narrow interval. Particularly, the first dummy patterns 222 may have a critical width and a critical interval of a photolithography process.

A first insulation layer pattern 226 is formed on upper faces of the first conductive layer patterns 224 and both side faces of the spacers 220. The first insulation layer pattern 226 may include a material having an etching selectivity different from that of the spacers 220. For example, the first insulation layer pattern 226 may include silicon oxynitride, silicon oxide, etc.

Second dummy patterns 228 are formed between the first dummy patterns 222 in the second region. The first dummy patterns 222 may have an upper face substantially coplanar with that of the second dummy patterns 228. Further, the second dummy patterns 228 may include the same material as that of the first insulation layer pattern 226.

A second insulation layer 230 is formed on the first insulation layer pattern 226, the spacers 220 and the etch-stop layer patterns 216a in the first region, and the first dummy patterns 222 and the second dummy patterns 228 in the second region. The second insulation layer 230 may have a thickness less than half of an interval between the first insulation layer patterns 226. Thus, recesses are formed in the second insulation layer 230.

The second insulation layer 230 may include silicon oxynitride, silicon oxide, etc. Further, the first insulation layer pattern 226 and the second insulation layer 230 may be the same material or different materials.

The second conductive layer patterns 232 are formed in the recesses. The second conductive layer patterns 232 may have a lower face higher than that of each of the first conductive layer patterns 224. The second conductive layer patterns 232 may be used as a bit line. Further, the second conductive layer patterns 232 may be the same material as the first conductive layer patterns 224.

As mentioned above, the first conductive layer patterns 224 and the second conductive layer patterns 232, which have the lower faces placed on different horizontal planes, are formed in the first region. In contrast, the first conductive layer patterns 224 and the second conductive layer patterns 232 used as the bit line are not formed in the second region.

A second insulation interlayer 234 is formed on the second conductive layer patterns 232 and the second insulation layer 230. The second insulation interlayer 234 may include silicon oxide. Further, the second insulation interlayer 234 may have a flat upper face.

A first contact plug 240 is formed through the second insulation interlayer 234, the second insulation layer 230, the first insulation layer pattern 226, the first insulation interlayer 214 and the first conductive layer patterns 224. The first contact plug 240 is electrically connected to the first conductive layer patterns 224 and the substrate 200.

When the first contact plug 240 has a width less than that of each of the first conductive layer patterns 224, an opening is formed at a portion of the first conductive layer patterns 224 where the first contact plug 240 is formed. Further, an inner wall of the opening makes contact with a sidewall of the first contact plug 240.

When the first contact plug 240 has a width greater than that of each of the first conductive layer patterns 224, the portion of the first conductive layer patterns 224 where the first contact plug 240 is formed may have a physically cut shape. That is, the first conductive layer patterns 224 may include each of cut patterns. The cut face of the first conductive layer patterns 224 makes contact with the sidewall of the first contact plug 240. In this case, the physically cut patterns are connected to each other via the first contact plug 240 so that the first conductive layer patterns 224 may have a linear shape.

A second contact plug 242 is formed through the second insulation interlayer 234, the second insulation layer 230, the first insulation layer pattern 226, the first insulation interlayer 214 and the second conductive layer patterns 232. The second contact plug 242 is electrically connected to the second conductive layer patterns 232 and the substrate 200.

For the flash memory device of some embodiments, the first conductive layer patterns and the second conductive layer patterns may not be coplanar with each other. Thus, the first conductive layer patterns and the second conductive layer patterns may have small/reduced areas facing each other so that parasitic capacitance between the first conductive layer pattern and the second conductive layer pattern may be reduced. As a result, a signal transmission speed through the first conductive layer pattern and the second conductive layer patterns may become faster. Further, since malfunctions of the flash memory device caused by the parasitic capacitance may be reduced, the flash memory device may have improved operational characteristics.

Furthermore, the first conductive layer patterns 223 and the second conductive layer patterns 232 may not be formed on the first insulation interlayer 214 in the second region.

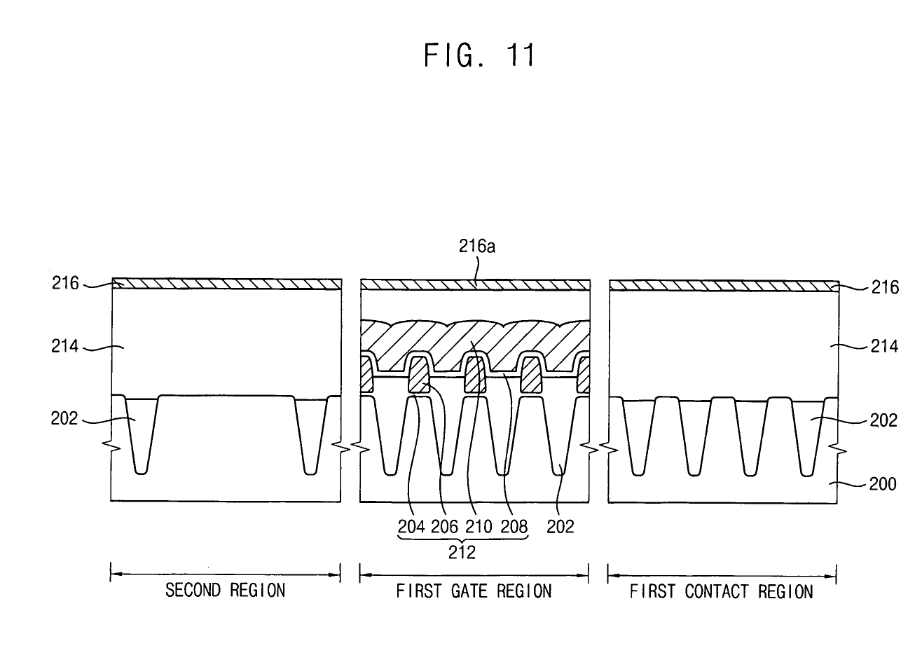

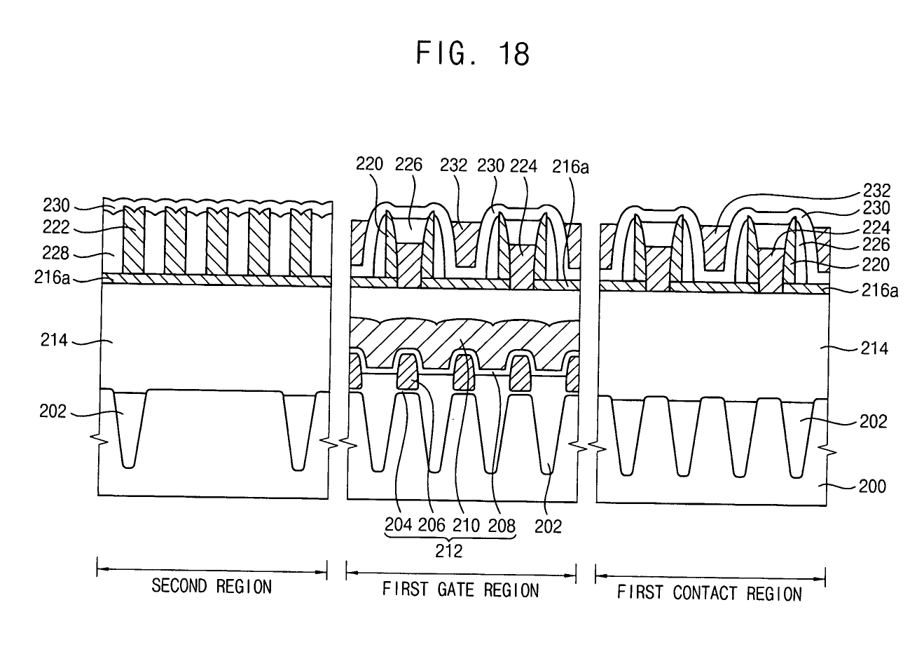

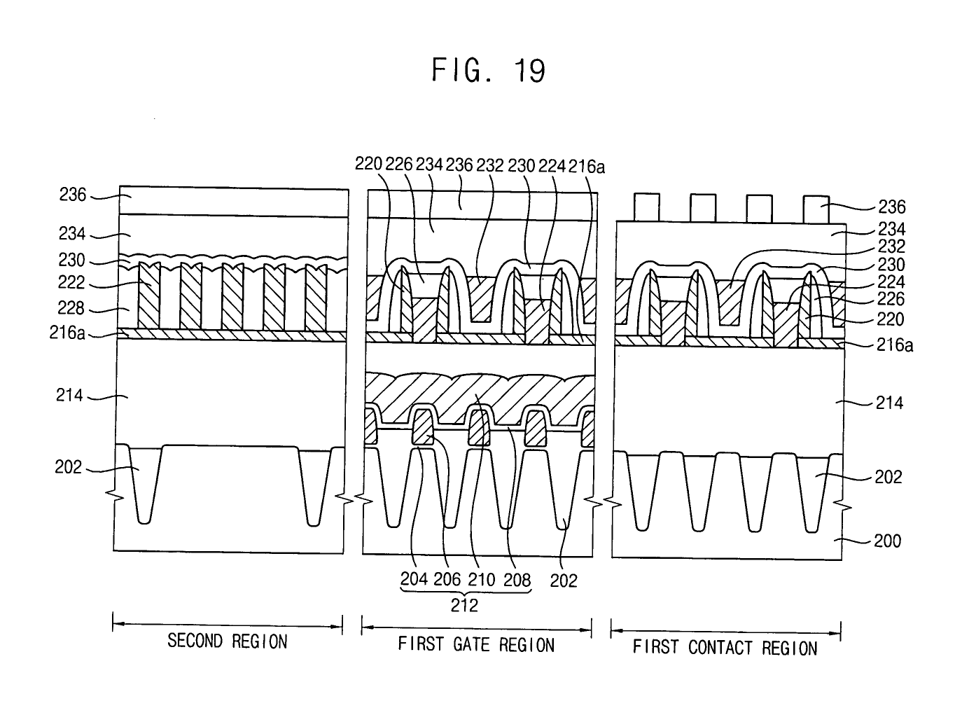

FIGS. 11 to 21 are cross-sectional views illustrating a method of manufacturing the flash memory device of FIGS. 9 and 10 according to some embodiments of the present invention. Referring to FIG. 11, the substrate 200 having the first region and the second region is prepared.

The substrate 200 is partially etched to form the trenches. The trenches are filled with an insulation layer to form the isolation layer patterns 202. The isolation layer patterns 202 divide the substrate 200 into active regions and the isolation regions.

The cell gate structures 212 are formed on the substrate 200 in the first region. Each of the cell gate structures 212 includes a tunnel oxide layer 204, a charge storage layer pattern 206, a dielectric layer pattern 208 and a control gate electrode 210 sequentially stacked. Impurity regions are formed at both sides of the cell gate structures 212 to complete the cell transistor.

The charge storage layer pattern 206 may include polysilicon doped with impurities. In this case, the charge storage layer pattern 206 may be used as a floating gate electrode. The charge storage layer pattern 206 may include silicon nitride and the charge storage layer pattern 206 may be used as a charge-trapping pattern.

The cell selection transistor and a ground selection transistor are connected to both ends of the cell transistor in the single string that includes the sixteen or thirty-two cell transistors. Here, the selection transistor and the ground selection transistor may have a MOS structure. When the charge storage pattern 206 includes polysilicon, a portion of the dielectric layer 208 where the cell selection transistor and the ground selection transistor are formed may be selectively removed to form gate patterns of the cell selection transistor and the ground selection transistor.

The first insulation interlayer 214 is formed on the substrate 200 to cover the cell transistor, the cell selection transistor and the ground selection transistor and the second region. The first insulation interlayer 214 may be formed by a CVD process using silicon oxide. Further, after forming the first insulation interlayer 214, a planarization process may be additionally performed to planarize the upper face of the first insulation interlayer 214. The planarization process may include a CMP process.

An etch-stop layer 216 is formed on the first insulation interlayer 214. The etch-stop layer 216 may be formed by a CVD process using silicon nitride.

A sacrificial layer is formed on the etch-stop layer 216. The sacrificial layer may include a material having etching selectivity with respect to the etch-stop layer 216. For example, the sacrificial layer 106 may include silicon oxide, polysilicon, etc.

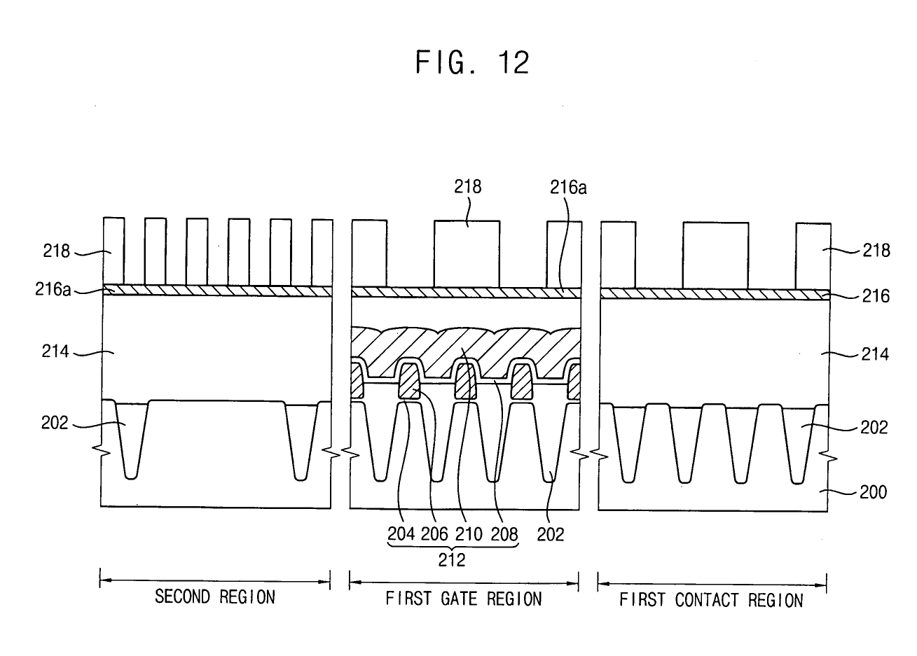

As seen in FIG. 12, the sacrificial layer is patterned by a photolithography process to form sacrificial layer patterns 218 in the first region and the second region. The first conductive layer patterns are formed in a region between the sacrificial layer patterns 218 in the first region. Further, the second conductive layer patterns are formed in a region where the sacrificial layer patterns 218 are formed. The first dummy patterns are formed between the sacrificial layer patterns 218 in the second region.

Each of the sacrificial layer patterns 218 may have a very narrow width. Furthermore, the sacrificial layer patterns 218 may be arranged spaced apart from each other by a very narrow interval. Particularly, the sacrificial layer patterns 218 may have a critical width and a critical interval of a photolithography process.

A silicon nitride layer is formed on the sacrificial layer pattern 218 and the etch-stop layer 216. A space between the sacrificial layer patterns 218 in the second region may be fully filled with the silicon nitride layer.

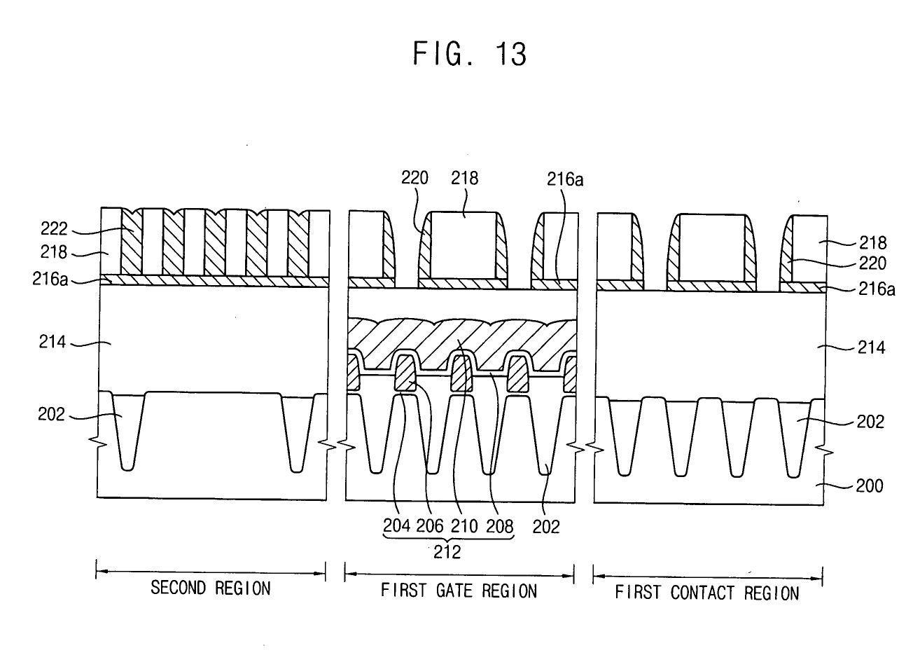

As seen in FIG. 13, the silicon nitride layer is anisotropically etched to form the spacers 220 on sidewalls of the sacrificial layer patterns 218 in the first region. Further, the first dummy patterns 222 are formed between the sacrificial layer patterns 218 in the second region.

In some embodiments, as the etch-stop layer 216 includes silicon nitride, the etch-stop layer 216 exposed by the spacers 220 is removed during the anisotropic etching process to form the etch-stop layer patterns 216a.

A first conductive layer is formed on the sacrificial layer patterns 218 and the first dummy patterns 222 to fill up the spaces between the spacers 220. The first conductive layer may include a metal, a semiconductor material doped with impurities, etc. Examples of a material that may be used for the first conductive layer may include tungsten, tungsten silicide, copper, polysilicon, etc.

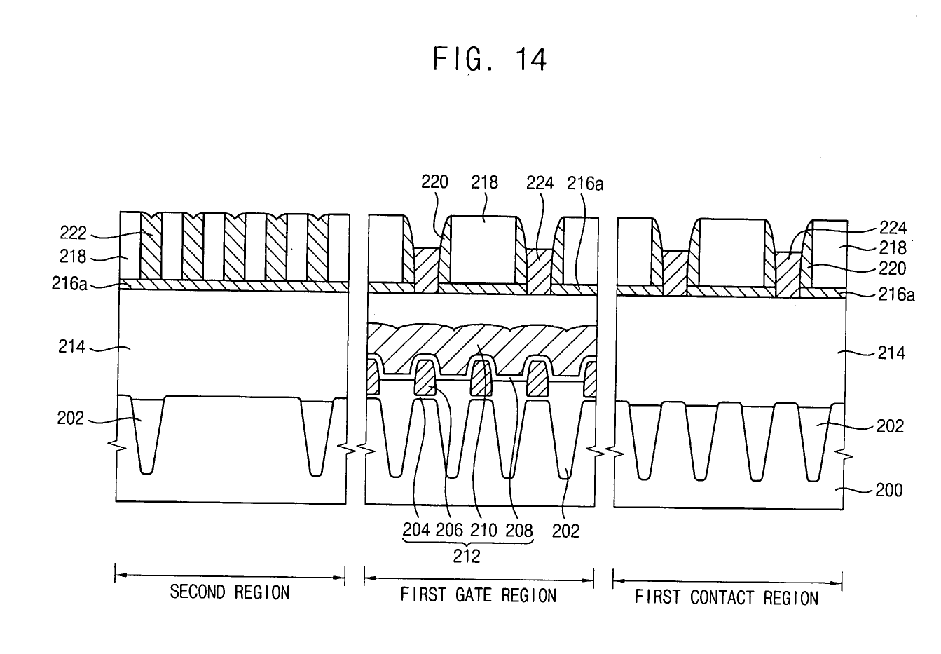

As seen in FIG. 14, the first conductive layer is partially removed to form the first conductive layer patterns 224 between the spacers 220. Here, each of the first conductive layer patterns 224 may have an upper face lower than that of each of the spacers 220. In this example embodiment, the first conductive layer may be removed by a CMP process, an etch-back process, etc. Further, during the removal of the first conductive layer, a portion of the first conductive layer in the second region may be completely removed.

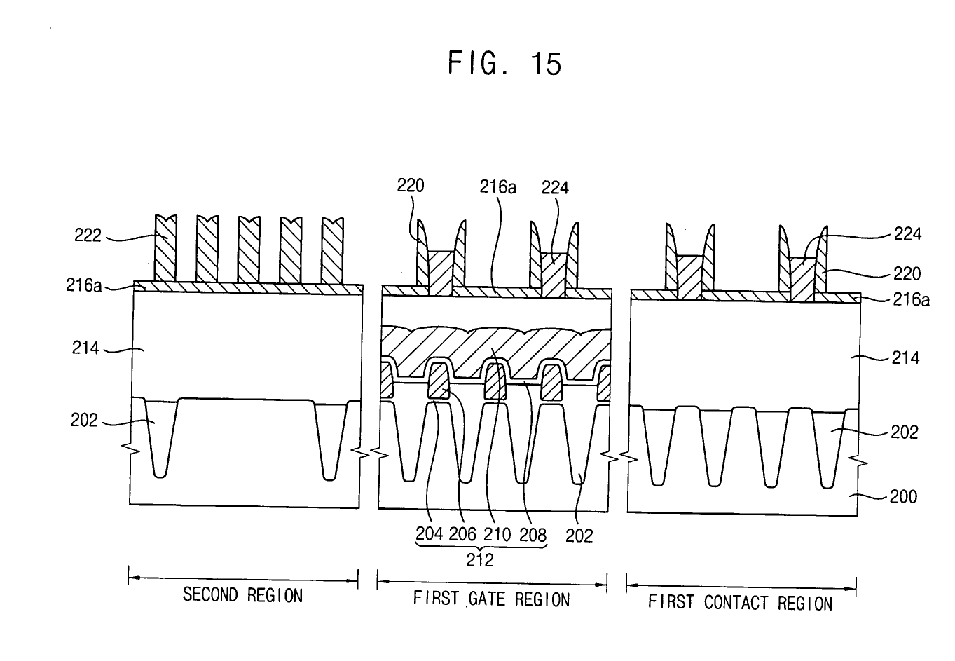

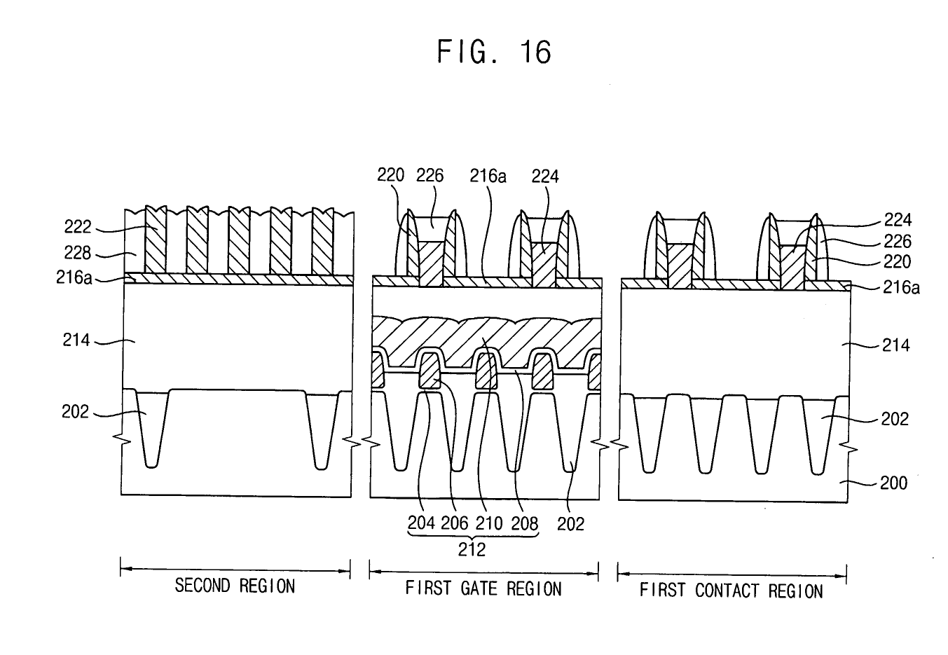

Referring to FIG. 15, the sacrificial layer pattern 218 is then removed. Here, to reduce the risk the spacers 220 and the first conductive layer patterns 224 may be damaged during the removal of the sacrificial layer pattern 218, the sacrificial layer pattern 218 may be removed by a wet etching process.

A first insulation layer is formed on the first region and the second region. Particularly, the first insulation layer is formed on the first conductive layer patterns 224, the spacers 220 and the etch-stop layer patterns 216a. Here, a space between the first conductive layer patterns 224 may not be completely filled with the first insulation layer. In contrast, a space between the first dummy patterns 222 in the second region may be completely filled with the first insulation layer.

The first insulation layer may be the same material or different from that of the spacers 220. For example, the first insulation layer may include silicon oxynitride, silicon oxide, silicon nitride, etc. The silicon oxynitride may be deposited by a CVD process to form the first insulation layer.

As seen in FIG. 16, the first insulation layer is anisotropically etched to form the first insulation layer pattern 226 on the sidewalls of the spacers 220 and the first conductive layer patterns 224. The first insulation layer pattern 226 on the sidewalls of the spacers 220 may have a general spacer shape. Further, when the first insulation layer is anisotropically etched, the second dummy patterns 228 are formed between the first dummy patterns 222 in the second region.

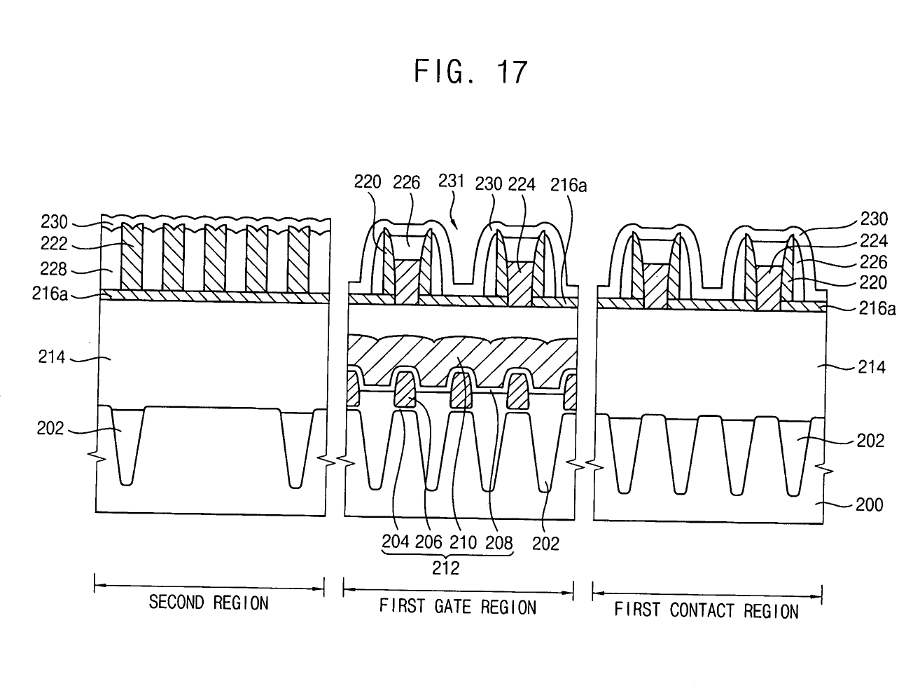

Referring to FIG. 17, the second insulation layer 230 is formed on the first insulation layer pattern 226, the spacers 220, the etch-stop layer patterns 216a, the first dummy patterns 222 and the second dummy patterns 228. The second insulation layer 230 may be the same material as or different material than the first insulation layer pattern 226. Further, the recesses 231 are formed between the first insulation layer patterns 226 by forming the second insulation layer 230. Each of the recesses 231 may have a bottom face higher than a lower face of each of the first conductive layer patterns 224.

A second conductive layer is formed on the second insulation layer 230 to fill up the recesses 231. The second conductive layer may be the same material as the first conductive layer pattern 224.

The second conductive layer is partially removed to form the second conductive layer patterns 232 in the recesses 231. The removal of the second conductive layer may be performed by an etch-back process, a CMP process, etc. Here, the second conductive layer in the second region may be completely removed.

Referring to FIG. 19, the second insulation interlayer 234 is formed on the second conductive layer patterns 232 and the second insulation layer 230. The second insulation interlayer 234 may include silicon oxide.

A photoresist film is formed on the second insulation interlayer 234. The photoresist film is patterned by a photolithography process to form a photoresist pattern having openings that expose portions corresponding to the first conductive layer patterns 224 and the second conductive layer patterns 232. In some embodiments, a hard mask pattern may be formed as an etching mask on the second insulation interlayer 234.

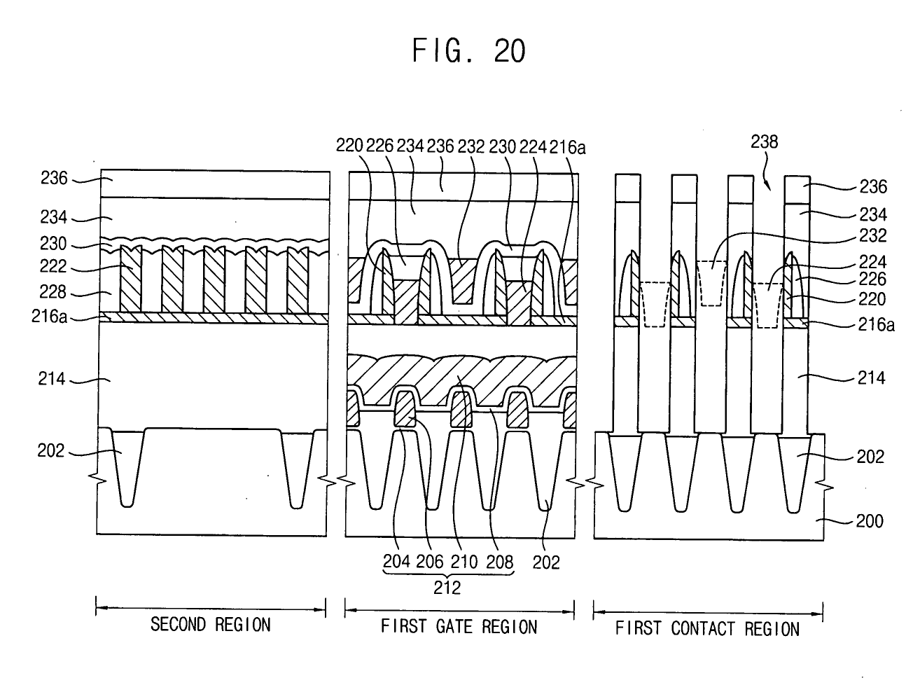

Referring to FIG. 20, the second insulation interlayer 234, the second insulation layer 230, the first conductive layer patterns 224, the second conductive layer patterns 232, the first insulation layer pattern 226 and the first insulation interlayer 214 are sequentially etched using the photoresist pattern 236 as an etching mask to form openings 238. After forming the openings 238, the photoresist pattern 236 may then removed by an ashing process and/or a stripping process.

A third conductive layer (not shown) is formed to fill up the openings 238. The third conductive layer may include polysilicon doped with impurities, tungsten silicide, tungsten, copper, etc. These can be used alone or in a combination thereof.

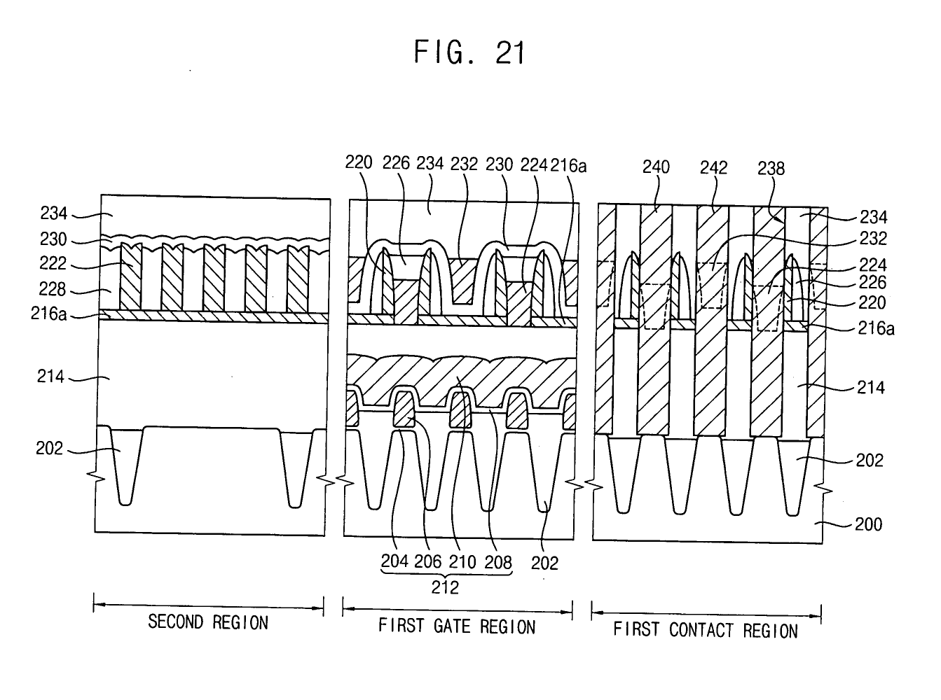

As seen in FIG. 21, the third conductive layer is partially removed by a CMP process until an upper face of the second insulation interlayer 234 is exposed to form the first contact plug 240 and the second contact plug 242. Here, the first contact plug 240 makes contact with the first conductive layer patterns 224 and the substrate 200. Further, the second contact plug 242 makes contact with the second conductive layer patterns 232 and the substrate 200.

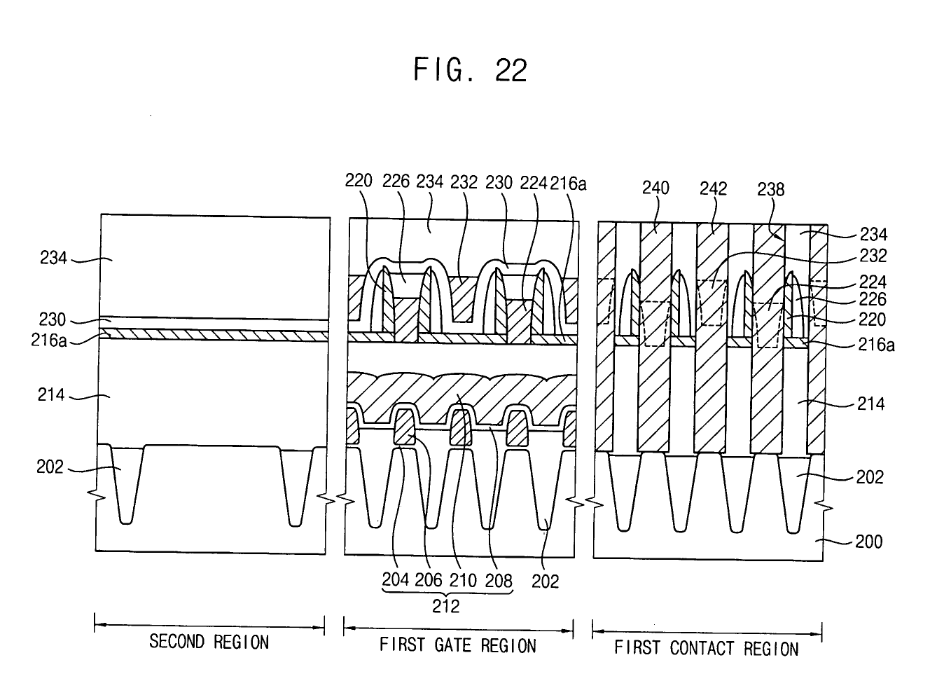

Further embodiments will now be described with reference to FIG. 22. FIG. 22 is a cross-sectional view illustrating a peripheral circuit region of a flash memory device in accordance with some embodiments of the present invention.

The flash memory device of FIG. 22 includes the same cell region as that described previously and a peripheral circuit region different from that of the flash memory device described previously. Thus, only the peripheral circuit region of the flash memory device of FIG. 22 will be described in detail.

Referring to FIG. 22, a substrate 200 has a first region where unit cells are formed, and a second region where peripheral circuits are formed. Isolation layer patterns 202 are formed on an isolation region of the substrate 200 in the second region. A first insulation interlayer 214 is formed on the substrate 200. Etch-stop layer patterns 216a are formed on the first insulation interlayer 214.

A second insulation layer 230 and a second insulation interlayer 234 are formed on the first insulation interlayer 214 in the second region. That is, the first dummy patterns and the second dummy patterns are not formed on the first insulation interlayer 214 in the second region as shown in the embodiments of FIG. 9. Thus, the second insulation layer 230 in the second region has an upper face lower than that of the second insulation layer 230 in the first region. In contrast, the second insulation interlayer 234 in the first region and the second region has a flat upper face without a stepped portion.

Further, a conductive layer of the first conductive layer patterns 224 and the second conductive layer patterns 232 is not formed on the first insulation interlayer 214 in the second region.

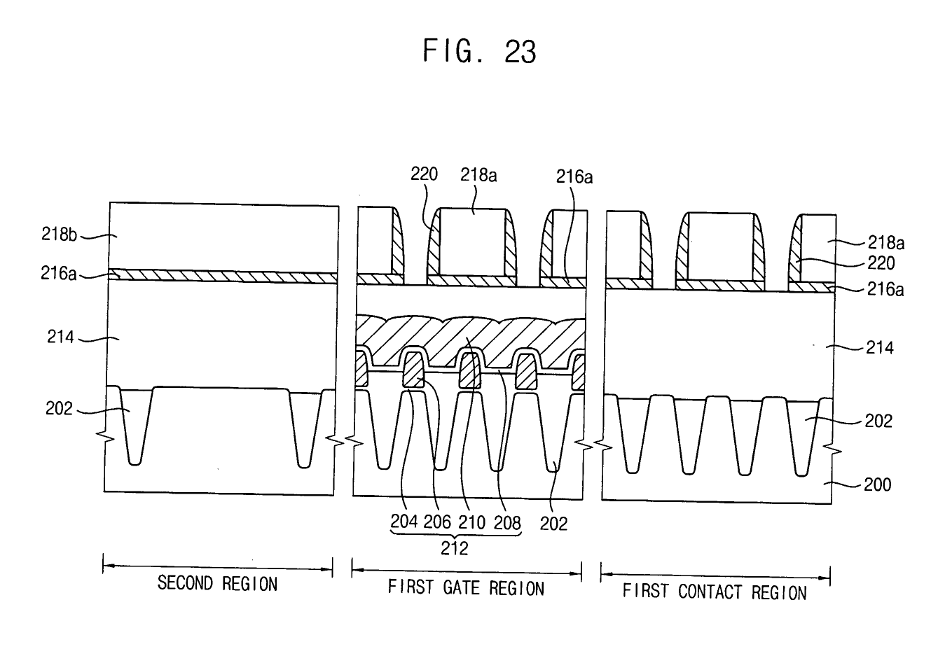

FIGS. 23 to 27 are cross-sectional views illustrating a method of manufacturing the flash memory device in FIG. 22 according to some embodiments of the present invention. Referring to FIG. 23, processes substantially the same as those described with reference to FIG. 11 are performed to form the cell gate structure 212, the first insulation interlayer 214 and the etch-stop layer 216.

A sacrificial layer 218b is formed on the etch-stop layer 216. The sacrificial layer 218b is patterned by a photolithography process to form sacrificial layer patterns 218a in the first region and the second region. Here, a portion of the sacrificial layer 218b in the second region is not etched. Thus, the portion of the sacrificial layer 218b in the second region still remains.

A silicon nitride layer is formed on the sacrificial layer pattern 218a in the first region and on the etch-stop layer 216 and the sacrificial layer 218b in the second region. The silicon nitride layer is anisotropically etched to form the spacers 220 on sidewalls of the sacrificial layer patterns 218a in the first region. Here, the silicon nitride layer on the sacrificial layer 218b in the second region is shown as completely removed by the anisotropic etching process. When the etch-stop layer 216 includes silicon nitride, the etch-stop layer 216 exposed by the spacers 220 may be removed during the anisotropic etching process to form the etch-stop layer patterns 216a.

A first conductive layer is formed on the sacrificial layer patterns 218a in the first region and the sacrificial layer 218b in the second region to fill up the spaces between the spacers 220. The first conductive layer may include a metal, a semiconductor material doped with impurities, etc. Examples of a material that may be used for the first conductive layer may include tungsten, tungsten silicide, copper, polysilicon, etc.

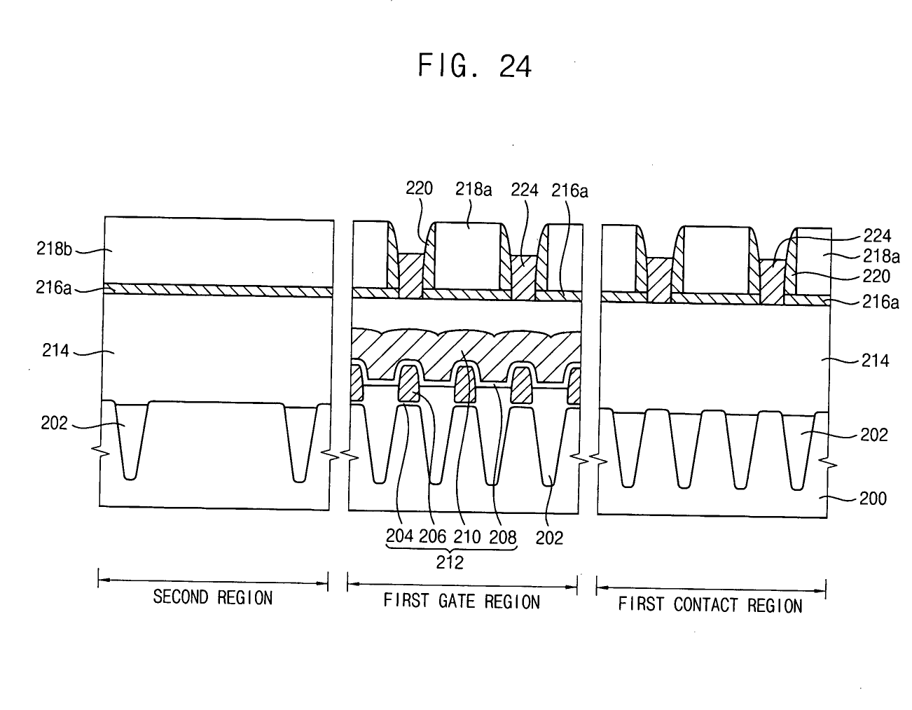

As seen in FIG. 24, the first conductive layer is partially removed to form the first conductive layer patterns 224 between the spacers 220. Each of the first conductive layer patterns 224 may have an upper face lower than that of each of the spacers 220. The first conductive layer may be removed by a CMP process, an etch-back process, etc. Further, during the removal of the first conductive layer, a portion of the first conductive layer in the second region may be completely removed.

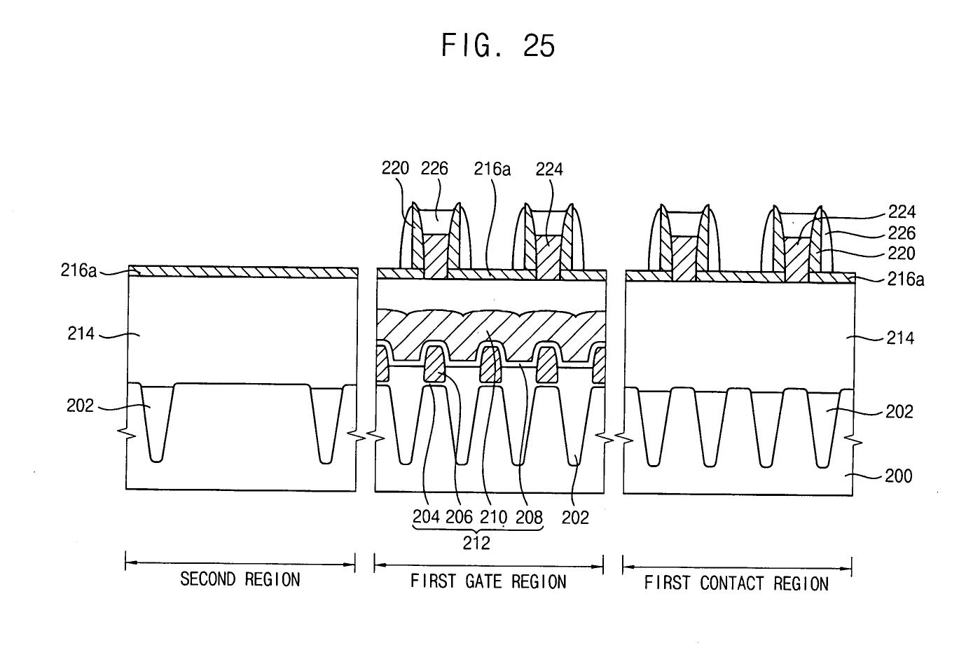

Referring to FIG. 25, the sacrificial layer pattern 218a in the first region and the sacrificial layer 218b in the second region are then removed. To limit damage to the spacers 220 and the first conductive layer patterns 224 during the removal of the sacrificial layer pattern 218a and the sacrificial layer 218b, the sacrificial layer pattern 218a and the sacrificial layer 218b may be removed by a wet etching process.

A first insulation layer is formed on the first region and the second region. Particularly, the first insulation layer is formed on the first conductive layer patterns 224, the spacers 220 and the etch-stop layer patterns 216a in the first region. In contrast, the first insulation layer is formed on the etch-stop layer patterns 216a in the second region.

The first insulation layer may include the same material as or different from that of the spacers 220. For example, the first insulation layer may include silicon oxynitride, silicon oxide, silicon nitride, etc. The silicon oxynitride may be deposited by a CVD process to form the first insulation layer.

As seen in FIG. 25, the first insulation layer is anisotropically etched to form the first insulation layer pattern 226 on the sidewalls of the spacers 220 and the first conductive layer patterns 224. Here, the first insulation layer pattern 226 on the sidewalls of the spacers 220 may have a general spacer shape. Further, the first insulation layer in the second region may be completely removed by the anisotropic etching process.

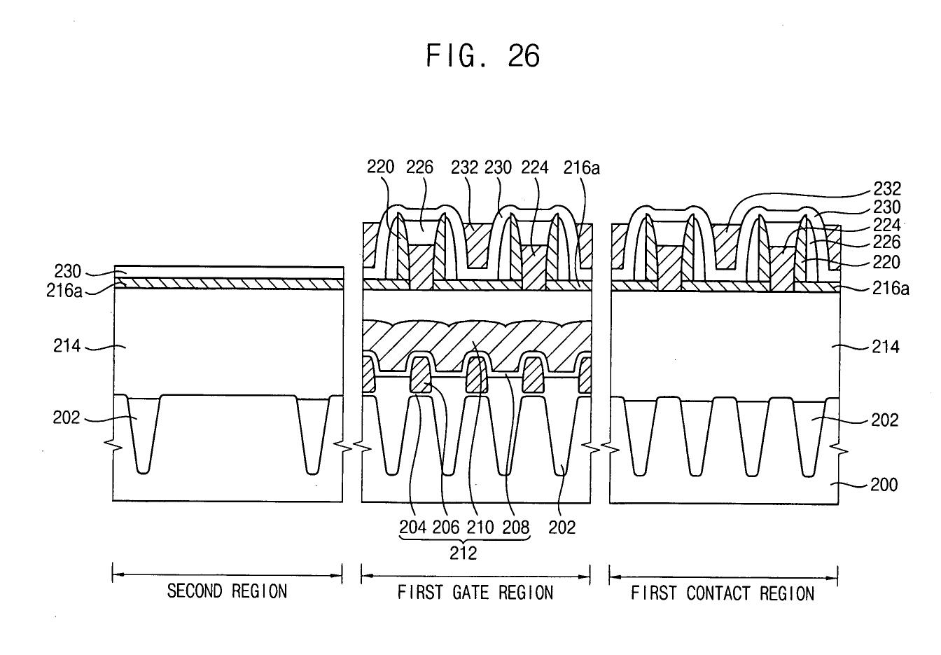

Referring to FIG. 26, the second insulation layer 230 is formed on the first insulation layer pattern 226, the spacers 220 and the etch-stop layer patterns. The second insulation layer 230 may be the same material or a different material than the first insulation layer pattern 226. Further, the recesses are formed between the first insulation layer patterns 226 by forming the second insulation layer 230. Each of the recesses may have a bottom face higher than a lower face of each of the first conductive layer patterns 224.

A second conductive layer is formed on the second insulation layer 230 to fill up the recesses. The second conductive layer may include the same material as the first conductive layer pattern 224.

As seen in FIG. 26, the second conductive layer is partially removed to form the second conductive layer patterns 232 in the recesses 231. The removal of the second conductive layer may be performed by an etch-back process, a CMP process, etc. The second conductive layer in the second region may be completely removed.

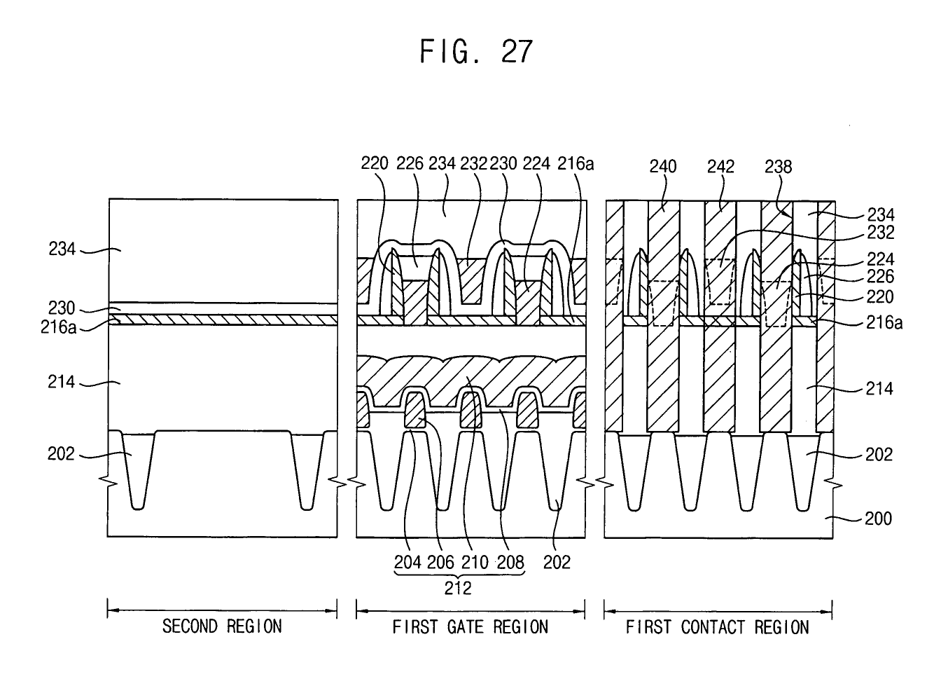

Referring to FIG. 27, the second insulation interlayer 234 is formed on the second conductive layer patterns 232 and the second insulation layer 230. The second insulation interlayer 234 may include silicon oxide. Additionally, after forming the second insulation interlayer 234, a planarization process for planarizing an upper face of the second insulation interlayer 234 may be performed.

A photoresist film is formed on the second insulation interlayer 234. The photoresist film is patterned by a photolithography process to form a photoresist pattern having openings that expose portions corresponding to the first conductive layer patterns 224 and the second conductive layer patterns 232. In some embodiments, a hard mask pattern may be formed as an etching mask on the second insulation interlayer 234.

The second insulation interlayer 234, the second insulation layer 230, the first conductive layer patterns 224, the second conductive layer patterns 232, the first insulation layer pattern 226 and the first insulation interlayer 214 are sequentially etched using the photoresist pattern as an etching mask to form openings 238. After forming the openings 238, the photoresist pattern may be removed by an ashing process and/or a stripping process.

A third conductive layer is formed to fill up the openings 238. Materials that may be used for the third conductive layer include polysilicon doped with impurities, tungsten silicide, tungsten, copper, etc. These can be used alone or in a combination thereof.

As seen in FIG. 27, the third conductive layer is partially removed by a CMP process until an upper face of the second insulation interlayer 234 is exposed to form the first contact plug 240 and the second contact plug 242. The first contact plug 240 makes contact with the first conductive layer patterns 224 and the substrate 200. Further, the second contact plug 242 makes contact with the second conductive layer patterns 232 and the substrate 200.

According some embodiments of the present invention, adjacent conductive layer patterns may be placed on different horizontal planes so that parasitic capacitance between the adjacent conductive layer patterns may be reduced. Further, the number of photolithography processes for forming the conductive structure may not be increased so that costs for manufacturing the flash memory device may not be greatly increased. Therefore, the semiconductor device, such as the flash memory, including the conductive structure may have improved performance.

The foregoing is illustrative of the present invention and is not to be construed as limiting thereof. Although a few embodiments of the present invention have been described, those skilled in the art will readily appreciate that many modifications are possible in the embodiments without materially departing from the novel teachings and advantages of this invention. Accordingly, all such modifications are intended to be included within the scope of the present invention as defined in the claims. Therefore, it is to be understood that the foregoing is illustrative of the present invention and is not to be construed as limited to the specific embodiments disclosed, and that modifications to the disclosed embodiments, as well as other embodiments, are intended to be included within the scope of the appended claims. The present invention is defined by the following claims, with equivalents of the claims to be included therein.

What is claimed is:

1. A conductive structure in an integrated circuit device, comprising:
an integrated circuit substrate;
first conductive layer patterns on the substrate; and
second conductive layer patterns on the substrate extending between respective ones of the first conductive layer patterns, wherein adjacent ones of the first and second conductive layer patterns are on different horizontal planes relative to the substrate to reduce parasitic capacitance therebetween.

2. The conductive structure of claim 1, further comprising:
a first insulation interlayer on the substrate, wherein the first conductive layer patterns are on the first insulation interlayer; and
an insulation member covering the first conductive layer patterns, the insulation member defining recesses between the first conductive layer patterns and wherein the second conductive layer patterns are in the recesses and wherein the second conductive layer patterns have a lower face higher than a lower face of the first conductive layer patterns to provide the different horizontal planes.

3. The conductive structure of claim 2, wherein the insulation member comprises silicon oxynitride, silicon nitride and/or silicon oxide.

4. The conductive structure of claim 2, further comprising a spacer contacting sidewalls of the first conductive layer patterns, the spacer having an upper face higher than an upper face of the first conductive layer patterns.

5. The conductive structure of claim 2, wherein the first conductive layer patterns and the second conductive layer pattern have an upper width and a lower width, wherein the lower width is narrower than the upper width.

6. The conductive structure of claim 2, wherein an underlying structure in a unit cell of a memory device is on the substrate under the conductive layer patterns.

7. The conductive structure of claim 6, wherein the underlying structure includes a tunnel oxide layer, a charge storage pattern, a dielectric layer and a control gate.

8. The conductive structure of claim 2, further comprising an etch-stop layer pattern on the first insulation interlayer.

9. The conductive structure of claim 2, wherein the insulation member comprises:
a first insulation layer pattern on upper faces of the first conductive layer patterns; and
a second insulation layer on the first insulation layer pattern and extending between adjacent ones of the first conductive layer patterns to define the recesses therebetween.

10. A non-volatile memory device including the conductive structure of claim 2 and further comprising:
a first region and a second region in the substrate, wherein the first insulation interlayer and the insulation member are on the first region and the second region of the substrate and the first and second conductive layer patterns are in the first region of the substrate;
unit cells on the first region of the substrate, the unit cells including an associated gate structure including a tunnel oxide layer, a charge storage pattern, a dielectric layer and a control gate;
a second insulation interlayer on the second conductive layer patterns in the first region and the insulation member in the second region;
a first contact plug extending through the second insulation interlayer, the insulation member, the first conductive layer patterns and the first insulation interlayer to contact the substrate, the first contact plug being electrically connected to the first conductive layer patterns; and
a second contact plug extending through the second insulation interlayer, the insulation member, the second conductive layer patterns and the first insulation interlayer to contact the substrate, the second contact plug being electrically connected to the second conductive layer patterns.

11. The non-volatile memory device of claim 10, further comprising first dummy patterns and second dummy patterns on the first insulation interlayer in the second region.

12. The non-volatile memory device of claim 10, wherein the insulation member comprises:
a first insulation layer pattern on upper faces of the first conductive layer patterns; and
a second insulation layer on the first insulation layer pattern and extending between adjacent ones of the first conductive layer patterns to define the recesses therebetween, wherein the first insulation layer pattern is not in the second region and the second insulation layer extends into the second region.

13. A method of forming a conductive structure, comprising:
forming a first insulation interlayer on a substrate;
forming first conductive layer patterns on the first insulation interlayer;
forming an insulation member that covers the first conductive layer patterns and defines recesses between adjacent ones of the first conductive layer patterns; and
forming second conductive layer patterns in the recesses of the insulation member, the second conductive layer patterns having a lower face higher than a lower face of the first conductive layer patterns so that adjacent ones of the first and second conductive layer patterns are on different horizontal planes relative to the substrate to reduce parasitic capacitance therebetween.

14. The method of claim 13, wherein forming the first conductive layer patterns comprises:
forming sacrificial layer patterns on the first insulation interlayer;
filling a space between the sacrificial layer patterns with a first conductive layer; and
partially removing the first conductive layer to form the first conductive layer patterns in the space between the sacrificial layer patterns.

15. The method of claim 14, further comprising forming a spacer on a sidewall of each of the sacrificial layer patterns.

16. The method of claim 14, wherein partially removing the first conductive layer is followed by removing the sacrificial layer patterns.

17. The method of claim 13, wherein forming the insulation member comprises:
forming a first insulation layer on the first conductive layer patterns and the first insulation interlayer;
partially etching the first insulation layer until a portion of the first insulation layer on the first insulation interlayer is removed to form a first insulation layer pattern; and
forming a second insulation layer on the first insulation interlayer and the first insulation layer pattern.

18. The method of claim 17, wherein the first insulation layer pattern has a spacer shape on a sidewall of each of the first conductive layer patterns.

19. The method of claim 13, wherein forming the second conductive layer pattern comprises:
forming a second conductive layer on the insulation member that fills the recesses of the insulation member; and
partially removing the second conductive layer to form the second conductive layer pattern in the recesses.

20. The method of claim 13, further comprising forming an etch-stop layer on the first insulation interlayer.

21. A method of manufacturing a non-volatile memory device structure, comprising:
providing a substrate having a first region and a second region;
forming unit cells on the first region of the substrate, each of the unit cells including a tunnel oxide layer, a charge storage pattern, a dielectric layer and a control gate;
forming a first insulation interlayer on the first region and the second region of the substrate;
forming first conductive layer patterns on the first insulation interlayer in the first region;
forming an insulation member covering the first conductive layer patterns in the first region, the insulation member defining recesses between adjacent ones of the first conductive layer patterns;
forming second conductive layer patterns in the recesses of the insulation member, the second conductive layer patterns having a lower face higher than that of the first conductive layer patterns;
forming a second insulation interlayer on the second conductive layer patterns in the first region and on the insulation member in the second region;
partially etching the second insulation interlayer, the insulation member, the first insulation interlayer, the first conductive layer patterns and the second conductive layer patterns until an upper face of the substrate is exposed to form openings; and
filling the openings with a conductive material to form a first contact plug electrically connected to the first conductive layer patterns and contacting the substrate and a second contact plug electrically connected to the second conductive layer patterns and contacting the substrate.

22. The method of claim 21, wherein forming the first conductive layer patterns comprises:
forming a sacrificial layer on the first insulation interlayer in the first region and the second region;
partially etching the sacrificial layer in the first region to form a sacrificial layer pattern;
forming a first conductive layer in a space between the sacrificial layer patterns in the first region and the sacrificial layer on the second region; and
partially removing the first conductive layer in the second region to form the first conductive layer patterns in the space between the sacrificial layer patterns.

23. The method of claim 21, wherein forming the insulation member comprises:
forming a first insulation layer on the first conductive layer patterns and the first insulation interlayer that fills a space between the first conductive layer patterns in the second region;
partially etching the first insulation layer until a portion of the first insulation layer on the first insulation interlayer is removed to form a first insulation layer pattern; and
forming a second insulation layer on the first insulation interlayer and the first insulation layer pattern.

24. The method of claim 21, further comprising forming an etch-stop layer on the first insulation interlayer.

25. The method of claim 21, wherein forming the first conductive layer patterns is preceded by forming spacers on both sides of the first dummy pattern in the second region and the first conductive layer patterns.

26. The method of claim 25, wherein forming the first dummy patterns and the spacers comprises:
forming sacrificial layer patterns on the first insulation interlayer in the first region and the second region;
forming a first insulation layer on the sacrificial layer patterns that fills spaces between the sacrificial layer patterns in the second region; and
anisotropically etching the first insulation layer to form the first dummy patterns between the sacrificial layer patterns in the second region and the spacers on the sidewall of the sacrificial layer patterns in the first region.

27. The method of claim 26, wherein forming the first conductive layer patterns comprises:
forming a first conductive layer that fills the space between the spacers in the first region; and
partially removing the first conductive layer to form the first conductive layer patterns in the space between the spacers.
